(19) United States
(12) Patent Application Publication
(10) Pub. No.: US 2004/0195668 A1
(43) Pub. Date: Oct. 7, 2004

(54) Semiconductor device, electronic device, electronic equipment, method of manufacturing semiconductor device, and method of manufacturing electronic device

(76) Inventor: Toshihiro Sawamoto, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 10/772,572

(22) Filed: Feb. 5, 2004

(30) Foreign Application Priority Data
Feb. 6, 2003 (JP) 2003-029841

(51) Int. Cl. H01L 23/02

(52) U.S. Cl. 257/686

(57) ABSTRACT

A method is provided to realize a three-dimensional mounting structure of different types of packages. By bonding protruding electrodes and to lands which are formed on a first carrier substrate, second and third carrier substrates are mounted on the first carrier substrate so that ends of the second and third carrier substrates are arranged above a semiconductor chip.

### RELATED APPLICATIONS

The present application claims priority to Japanese Patent Application No. 2003-029841 filed Feb. 6, 2003 which is hereby expressly incorporated by reference herein.

### BACKGROUND

1. Field of the Invention

The present invention relates to a semiconductor device, an electronic device, electronic equipment, a method of manufacturing a semiconductor device, and a method of manufacturing an electronic device, and particularly to those suitable for being applied to a stacked structure of a semiconductor package and the like.

2. Description of the Related Art

In a conventional semiconductor device, in order to save space when mounting semiconductor chips, there has been a method of three-dimensionally mounting semiconductor chips while interposing the same type of carrier substrates, as disclosed in Japanese laid-open patent publication No. 10-284683.

However, in the method of three-dimensionally mounting semiconductor chips while interposing the same type of carrier substrates, stacking different types of packages and chips becomes difficult. Accordingly, there is a problem in that the effectiveness of saving space is not improved.

Therefore, the present invention is intended to provide a semiconductor device, an electronic device, electronic equipment, a method of manufacturing a semiconductor device, and a method of manufacturing an electronic device which can realize a three-dimensional mounting structure of different types of packages.

### SUMMARY

In order to solve the above-described problem, a semiconductor device according to an embodiment of the present invention includes a rectangle-shaped carrier substrate which has a first region including two sides adjacent to each other, and a second region which adjoins the first region with one diagonal line as a border and whose shape is symmetrical with respect to the first region. The semiconductor device also includes a semiconductor chip mounted on the carrier substrate, a first protruding electrode group arranged in an L-shape along the two sides of the first region, and a second protruding electrode group arranged on the second region so as to be asymmetrical with the arrangement of the first protruding electrode group.

Accordingly, the protruding electrode group can be arranged on the carrier substrate which is imbalanced, thereby enabling the carrier substrate to be supported through the protruding electrode group, while the region without a protruding electrode which is along at least one side of the carrier substrate can be arranged on the formation side of the protruding electrode group.

For this reason, the second carrier substrate where the second semiconductor chip is mounted can be supported on the first carrier substrate so that the end of the second carrier substrate is arranged above the first semiconductor chip mounted on the first carrier substrate. As such, different types of packages can be stacked while suppressing an increase in height.

Furthermore, a semiconductor device according to an embodiment of the present invention includes a rectangle-shaped carrier substrate, a semiconductor chip mounted on the carrier substrate, and a region without a protruding electrode that is provided along at least two sides which intersect at a first vertex of the carrier substrate. The semiconductor device also includes a protruding electrode group which is provided along at least two sides which intersect at a second vertex of the carrier substrate opposite the first vertex.

Accordingly, the second carrier substrate where the second semiconductor chip is mounted can be supported on the first carrier substrate so that the vertex of the second carrier substrate is arranged above the first semiconductor chip mounted on the first carrier substrate. Furthermore, because this enables a plurality of carrier substrates to be arranged above the same first semiconductor chip, the mounting area can be further reduced.

Furthermore, a semiconductor device according to an embodiment of the present invention includes a rectangle-shaped carrier substrate, a semiconductor chip mounted on the carrier substrate, and a region without a protruding electrode which is provided along at least a first side of the carrier substrate. The semiconductor device also includes a protruding electrode group which is provided along a second side of the carrier substrate opposite the first side, and along at least a third side which intersects the second side.

Accordingly, the second carrier substrate where the second semiconductor chip is mounted can be supported on the first carrier substrate so that the side of the second carrier substrate is arranged above the first semiconductor chip mounted on the first carrier substrate. Because this enables a plurality of carrier substrates to be arranged above the same first semiconductor chip, the mounting area can be further reduced.

Furthermore, in a semiconductor device according to an embodiment of the present invention, the protruding electrode group may be arranged in a U-shape.

Accordingly, even when the end of the carrier substrate is arranged above the semiconductor chip, the carrier substrate can be supported with at least four (4) corners of the carrier substrate. Therefore, the carrier substrate can be stably held, while enabling the stacking of different types of packages.

Furthermore, a semiconductor device according to an embodiment of the present invention includes a carrier substrate and a protruding electrode arranged on the carrier substrate, excluded from a region where a semiconductor chip is mounted so as to be arranged to be overlapped by an end of the carrier substrate.

Accordingly, the carrier substrate can be supported so that the end of the carrier substrate is arranged above the semiconductor chip. For this reason, a plurality of carrier substrates can be arranged above the same semiconductor chip, thereby enabling the mounting area to be reduced while enabling the stacking of different types of packages.

Furthermore, a semiconductor device according to an embodiment of the present invention includes a carrier substrate, a semiconductor chip mounted on the carrier substrate, a plurality of land electrodes formed on the carrier substrate, and a protruding electrode arranged on a part of the plurality of land electrodes.

Accordingly, even when the land electrodes are arranged on the carrier substrate according to a predetermined specification, the protruding portions of the protruding electrodes can be removed over a predetermined range. For this reason, the end of the carrier substrate can be arranged above the semiconductor chip, while attaining a wide use of the carrier substrate. As such, a plurality of carrier substrates can be arranged above the same semiconductor chip, while preventing the complication of the manufacturing process.

Furthermore, a semiconductor device according to an embodiment of the present invention includes a first carrier substrate, a first semiconductor chip mounted on the first carrier substrate, a rectangle-shaped second carrier substrate, and a second semiconductor chip mounted on the second carrier substrate. The semiconductor device also includes a region without a protruding electrode that is provided along at least two sides which intersect at a first vertex of the second carrier substrate, and a protruding electrode group which is provided along at least two sides which intersect at a second vertex of the second carrier substrate opposite the first vertex, and which is bonded to the first carrier substrate so as to arrange the first semiconductor chip under the region without a protruding electrode.

Accordingly, the second carrier substrate where the second semiconductor chip is mounted can be supported on the first carrier substrate so that the vertex of the second carrier substrate is arranged above the first semiconductor chip. Furthermore, because this enables a plurality of second carrier substrates to be arranged above the same first semiconductor chip, the mounting area can be reduced, while enabling the stacking of different types of chips.

Furthermore, a semiconductor device according to an embodiment of the present invention includes a first carrier substrate, a first semiconductor chip mounted on the first carrier substrate, a rectangle-shaped second carrier substrate, and a second semiconductor chip mounted on the second carrier substrate. The semiconductor device also includes a region without a protruding electrode that is provided along at least a first side of the second carrier substrate, and a protruding electrode group which is provided along a second side of the second carrier substrate opposite the first side, and along at least a third side which intersects the second side, and which is bonded to the first carrier substrate so as to arrange the first semiconductor chip under the region without a protruding electrode.

Accordingly, the second carrier substrate where the second semiconductor chip is mounted can be supported on the first carrier substrate so that the side of the second carrier substrate is arranged above the first semiconductor chip. Furthermore, because this enables a plurality of second carrier substrates to be arranged on the same first semiconductor chip, the mounting area can be reduced, while enabling the stacking of different types of chips.

Furthermore, a semiconductor device according to an embodiment of the present invention includes a first carrier substrate, a first semiconductor chip mounted on the first carrier substrate, and a rectangle-shaped second semiconductor chip. The semiconductor device also includes a region without a protruding electrode that is provided along at least two sides which intersect at a first vertex of the second semiconductor chip, and a protruding electrode group which is provided along at least two sides which intersect at a second vertex of the second semiconductor chip opposite the first vertex, and which is bonded to the first carrier substrate so as to arrange the first semiconductor chip under the region without a protruding electrode.

Accordingly, without interposing a carrier substrate between the first semiconductor chip and the second semiconductor chip, the second semiconductor chip can be supported above the first carrier substrate so that the vertex of the second semiconductor chip is arranged above the first semiconductor chip. For this reason, a plurality of second semiconductor chips can be arranged above the same first semiconductor chip, while suppressing an increase in height when stacking semiconductor chips. As such, the mounting area can be reduced, while enabling the stacking of different types of chips.

Furthermore, a semiconductor device according to an embodiment of the present invention includes a first carrier substrate, a first semiconductor chip mounted on the first carrier substrate, and a rectangle-shaped second semiconductor chip. The semiconductor device also includes a region without a protruding electrode which is provided along at least a first side of the second semiconductor chip, and a protruding electrode group which is provided along a second side of the second semiconductor chip opposite the first side, and along at least a third side which intersects the second side, and which is bonded to the first carrier substrate so as to arrange the first semiconductor chip under the region without a protruding electrode.

Accordingly, without interposing a carrier substrate between the first semiconductor chip and the second semiconductor chip, the second semiconductor chip can be supported on the first carrier substrate so that the side of the second semiconductor chip is arranged above the first semiconductor chip. For this reason, a plurality of second semiconductor chips can be arranged above the same first semiconductor chip, while suppressing an increase in height when stacking semiconductor chips.

Furthermore, an electronic device according to an embodiment of the present invention includes a first carrier substrate, a first electronic component mounted on the first carrier substrate, a rectangle-shaped second carrier substrate, and a second electronic component mounted on the second carrier substrate. The electronic device also includes a region without a protruding electrode that is provided along at least two sides which intersect at a first vertex of the second carrier substrate, and a protruding electrode group which is provided along at least two sides which intersect at a second vertex of the second carrier substrate opposite the first vertex, and which is bonded to the first carrier substrate so as to arrange the first electronic component under the region without a protruding electrode.

Accordingly, the second carrier substrate where the second electronic component is mounted can be supported on the first carrier substrate so that the vertex of the second carrier substrate is arranged above the first electronic component. Furthermore, because this enables a plurality of carrier substrates to be arranged above the same first electronic component, the mounting area can be further reduced.

Furthermore, an electronic device according to an embodiment of the present invention includes a first carrier substrate, a first electronic component mounted on the first carrier substrate, a rectangle-shaped second carrier substrate, and a second electronic component mounted on the second carrier substrate. The electronic device also includes a region without a protruding electrode which is provided along at least a first side of the second carrier substrate, and a protruding electrode group which is provided along a second side of the second carrier substrate opposite the first side, and along at least a third side which intersects the second side, and which is bonded to the first carrier substrate so as to arrange the first electronic component under the region without a protruding electrode.

Accordingly, the second carrier substrate where the second electronic component is mounted can be supported on the first carrier substrate so that the side of the second carrier substrate is arranged above the first electronic component. Furthermore, because this enables a plurality of carrier substrates to be arranged above the same first electronic component, the mounting area can be further reduced.

Furthermore, electronic equipment according to an embodiment of the present invention includes a first carrier substrate, a first semiconductor chip mounted on the first carrier substrate, a rectangle-shaped second carrier substrate, and a second semiconductor chip mounted on the second carrier substrate. The electronic equipment also includes a region without a protruding electrode that is provided along at least two sides which intersect at a first vertex of the second carrier substrate, and a protruding electrode group which is provided along at least two sides which intersect at a second vertex of the second carrier substrate opposite the first vertex, and which is bonded to the first carrier substrate so as to arrange the first semiconductor chip under the region without a protruding electrode, and a motherboard where the first carrier substrate is mounted.

Accordingly, a plurality of second carrier substrates can be supported on the first carrier substrate so that the vertexes of the second carrier substrates are arranged above the first semiconductor chip, and weight savings and miniaturization of electronic equipment can be attained, while enabling the functional characteristic of the electronic equipment to be improved.

Furthermore, electronic equipment according to an embodiment of the present invention includes a first carrier substrate, a first semiconductor chip mounted on the first carrier substrate, a rectangle-shaped second carrier substrate, and a second semiconductor chip mounted on the second carrier substrate. The semiconductor device also includes a region without a protruding electrode which is provided along at least a first side of the second carrier substrate, a protruding electrode group which is provided along a second side of the second carrier substrate opposite the first side, and along at least a third side which intersects the second side, and which is bonded to the first carrier substrate so as to arrange the first semiconductor chip under the region without a protruding electrode, and a motherboard where the first carrier substrate is mounted.

Accordingly, a plurality of second carrier substrates can be supported on the first carrier substrate so that the sides of the second carrier substrates are arranged above the first semiconductor chip, and weight savings and miniaturization of electronic equipment can be attained, while enabling the functional characteristic of the electronic equipment to be improved.

Furthermore, a method of manufacturing a semiconductor device according to an embodiment of the present invention includes the steps of mounting a first semiconductor chip on a first carrier substrate, mounting a second semiconductor chip on a second carrier substrate, and forming a protruding electrode group on the second carrier substrate while avoiding the periphery of at least one side of the second carrier substrate. The method also includes the step of bonding the protruding electrode group to the first carrier substrate so as to arrange the at least one side of the second carrier substrate on or above the first semiconductor chip.

Accordingly, by bonding the protruding electrode group to the first carrier substrate, the second carrier substrate can be supported above the first carrier substrate so that the vertex of the second carrier substrate is arranged above the first semiconductor chip. For this reason, different types of chips can be stacked by adjusting the position for arranging the protruding electrode group, and thus the effectiveness in saving space can be improved while preventing the complication of the manufacturing process.

Furthermore, a method of manufacturing a semiconductor device according to an embodiment of the present invention includes the steps of mounting a first semiconductor chip on a first carrier substrate, mounting a second semiconductor chip on a second carrier substrate, and forming a protruding electrode group on the second carrier substrate while avoiding the periphery of at least one vertex of the second carrier substrate. The method also includes the step of bonding the protruding electrode group to the first carrier substrate so as to arrange the at least one vertex of the second carrier substrate on or above the first semiconductor chip.

Accordingly, by bonding the protruding electrode group to the first carrier substrate, the second carrier substrate can be supported on the first carrier substrate so that the side of the second carrier substrate is arranged above the first semiconductor chip. For this reason, different types of chips can be stacked by adjusting the position for arranging the protruding electrode group, and thus the effectiveness in saving space can be improved while preventing the complication of the manufacturing process.

### BRIEF DESCRIPTION OF THE DRAWINGS

FIG. 1 is a sectional view showing a structure of a semiconductor device according to a first embodiment.

FIG. 2 is a plan view showing a method of arranging protruding electrodes according to a second embodiment.

FIG. 3 is a plan view showing a method of arranging protruding electrodes according to a third embodiment.

FIG. 4 is a plan view showing a method of arranging protruding electrodes according to a fourth embodiment.

FIG. 5 is a plan view showing a method of arranging protruding electrodes according to a fifth embodiment.

FIG. 6 is a plan view showing a method of arranging protruding electrodes according to a sixth embodiment.

FIG. 7 is a plan view showing a method of arranging protruding electrodes according to a seventh embodiment.

FIG. 8(a)-(c) are sectional views showing a method of manufacturing a semiconductor device according to an eighth embodiment.

FIG. 9 is a sectional view showing a structure of a semiconductor device according to a ninth embodiment.

FIG. 10 is a sectional view showing a structure of a semiconductor device according to a tenth embodiment.

FIG. 11 is a sectional view showing a structure of a semiconductor device according to an eleventh embodiment.

### DETAILED DESCRIPTION

Semiconductor devices, electronic devices and methods of manufacturing the same according to embodiments of the present invention will be described below with reference to drawings.

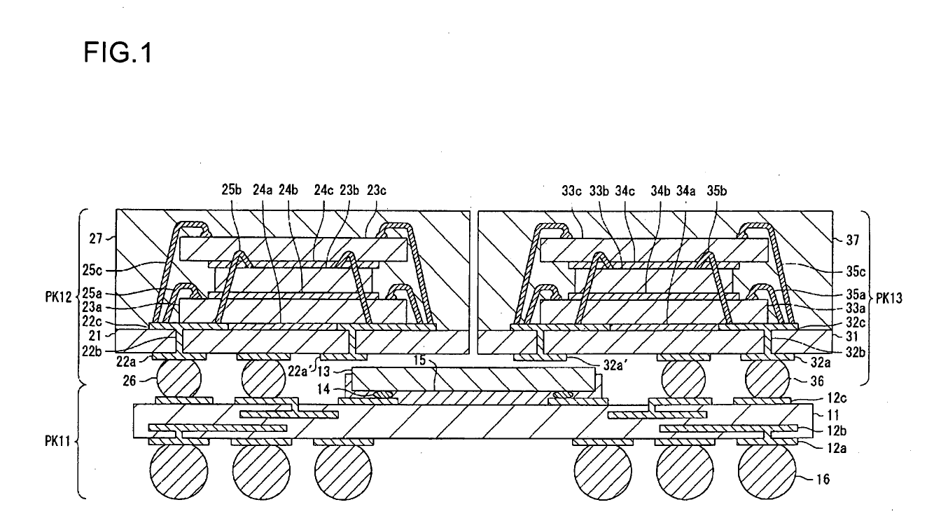

FIG. 1 is a sectional view showing a structure of a semiconductor device according to a first embodiment of the present invention. According to the first embodiment, a semiconductor package PK12 where semiconductor chips (or semiconductor die) 23a-23c of a stacked-structure are wire-bonded, and a semiconductor package PK13 where semiconductor chips (or semiconductor die) 33a-32c of a stacked-structure are wire-bonded, are stacked on a semiconductor package PK11 where a semiconductor chip (or semiconductor die) 13 is mounted by ACF (Anisotropic Conductive Film) bonding.

In FIG. 1, while the semiconductor package PK11 has a carrier substrate 11 provided therein and lands 12a and 12c are formed on both sides of the carrier substrate 11 respectively, and internal wirings 12b are formed inside the carrier substrate 11. Then, on the carrier substrate 11, the semiconductor chip 13 is flip-chip mounted, and protruding electrodes 14 for flip-chip mounting are formed on the semiconductor chip 13. Then, the protruding electrodes 14, which are formed on the semiconductor chip 13, are bonded to the lands 12c by ACF bonding through an anisotropic conductive sheet 15. Protruding electrodes 16 for mounting the carrier substrate 11 on a motherboard are formed on the lands 12a which are formed on the back surface of the carrier substrate 11.

By mounting the semiconductor chip 13 on the carrier substrate 11 by ACF bonding, the space for wire bonding and mold sealing becomes unnecessary. Therefore, space savings at the time of three-dimensional mounting can be attained, while enabling the temperature to be lowered when bonding the semiconductor chip 13 to the carrier substrate 11, thereby enabling the warping of the carrier substrate 11 in actual use to be reduced.

On the other hand, the semiconductor packages PK12 and PK13 have carrier substrates 21 and 31 provided therein, respectively. While lands 22a, 22a′, 32a, and 32a′ are formed on the back surface of the carrier substrates 21 and 31, respectively, lands 22c and 32c are formed on the top surface of the carrier substrates 21 and 31, respectively, and internal wirings 22b and 32b are formed inside the carrier substrates 21 and 31, respectively. Here, on the lands 22a and 32a, protruding electrodes 24 and 36 are arranged, respectively, while it is possible to leave the lands 22a′ and 32a′ so that the protruding electrodes 24 and 36 are not arranged thereon.

Then, on the carrier substrates 21 and 31, while semiconductor chips 23a and 33a are face-up mounted through adhesion layers 24a and 34a respectively, the semiconductor chips 23a and 33a are wire-bonded to lands 22c and 32c through conductive wires 25a and 35a respectively. Furthermore, on the semiconductor chips 23a and 33a, semiconductor chips 23b and 33b are face-up mounted respectively while avoiding the conductive wires 25a and 35a. Furthermore, the semiconductor chips 23b and 33b are fixed on the semiconductor chips 23a and 33a through adhesion layers 24b and 34b respectively, while being wire-bonded to the lands 22c and 32c through conductive wires 25b and 35b, respectively. Furthermore, on the semiconductor chips 23b and 33b, semiconductor chips 23c and 33c are face-up mounted respectively while avoiding the conductive wires 25b and 35b, and the semiconductor chips 23c and 33c are fixed on the semiconductor chips 23b and 33b through adhesion layers 24c and 34c respectively, while being wire-bonded to the lands 22c and 32c via conductive wires 25c and 35c respectively.

Moreover, on the lands 22a and 32a formed on the back surface of the carrier substrates 21 and 31, respectively, the protruding electrodes 24 and 36 are formed so as to mount the carrier substrates 21 and 31 on the carrier substrate 11 respectively. The carrier substrates 21 and 31 are held above the semiconductor chip 13 thereby. Here, it is preferable that the protruding electrodes 24 and 36 exist at least at the four corners of the carrier substrates 21 and 31, respectively, while avoiding the region for disposing the semiconductor chip 13. Accordingly, even when the carrier substrates 21 and 31 are mounted on the carrier substrate 11 so that the ends of the carrier substrates 21 and 31 are arranged above the semiconductor chip 13, the carrier substrates 21 and 31 can be stably held on the carrier substrate 11.

Moreover, the position for arranging the protruding electrodes 24 and 36 can be adjusted by providing the lands 22a′ and 32a′, where the protruding electrodes 24 and 36 are not disposed on the carrier substrates 21 and 31, respectively. For this reason, even when the types and sizes of the semiconductor chip 13 to be mounted on the carrier substrate 11 are changed, the protruding electrodes 24 and 36 can be re-arranged without changing the structures of the carrier substrates 21 and 31. As such, a wide use of the carrier substrates 21 and 31 can be attained.

By bonding the protruding electrodes 24 and 36 respectively to the lands 12c which are provided on the carrier substrate 11, the carrier substrates 21 and 31 can be mounted on the carrier substrate 11 so that the ends of the carrier substrates 21 and 31 are arranged above the semiconductor chip 13. Accordingly, a plurality of semiconductor packages PK12 and PK13 can be arranged above the same semiconductor chip 13. As such, a three-dimensional mounting of different types of the semiconductor chips 13, 23a-23c, 33a-33c can be attained while enabling a reduction of the mounting area.

Here, as for the semiconductor chip 13, for example, a logic processing element such as CPU, and as for the semiconductor chips 23a-23c and 33a-33c, for example, memory elements such as DRAM, SRAM, EEPROM, and a flash memory, can be used. Thereby while various functions can be realized, suppressing an increase of the mounting region, a stacked structure of memory elements can be easily realized, and the storage capacity can be easily increased.

In addition, when mounting the carrier substrates 21 and 31 on the carrier substrate 11, the back surfaces of the carrier substrates 21 and 31 may closely contact the semiconductor chip 13, or the back surfaces of the carrier substrates 21 and 31 may be spaced apart from the semiconductor chip 13.

Moreover, the side walls of the carrier substrate 21 and the carrier substrate 31 may closely contact each other or may be apart from each other. Here, by closely contacting the side walls of the carrier substrate 21 and the carrier substrate 31 to each other, it becomes possible to improve the packaging density of the semiconductor packages PK12 and PK13 to be mounted on the semiconductor package PK11, thereby enabling space savings. On the other hand, by separating the side walls of the carrier substrate 21 and the carrier substrate 31 from each other, it becomes possible to radiate the heat generated from the semiconductor chip 13 through the gap between the semiconductor packages PK12 and PK13, thereby enabling the radiation characteristic of the heat generated from the semiconductor chip 13 to be improved.

Moreover, sealing resin 27 and 37 is provided over the whole surface of the carrier substrates 21 and 31, respectively, at the mounting side of the semiconductor chips 23a-23c and 33a-33c, and thus the semiconductor chips 23a-23c and 33a-33c are sealed by the sealing resin 27 and 37, respectively. In addition, when sealing the semiconductor chips 23a-23c and 33a-33c by the sealing resin 27 and 37, respectively, molding where a thermosetting resin such as an epoxy resin is used can be executed.

In addition, as for the carrier substrates 11, 21, and 31, for example, a double-sided substrate, a multilayer-interconnection substrate, a build-up substrate, a tape substrate, or a film substrate, (among others) can be used, and as for the material of the carrier substrates 11, 21 and 31, for example, a polyimide resin, a glass epoxy resin, BT resin, a composite of aramid and epoxy, ceramic, or the like can be used. Moreover, as for the protruding electrodes 14, 24 and 36, for example, an Au bump, Cu bump or Ni bump covered with a solder material and the like, a solder ball, or the like can be used, and as for the conductive wires 25a-25c and 35a-35c, for example, Au wire, aluminum wire, and the like can be used. Moreover, in the embodiment described above, a method of forming the protruding electrodes 24 and 36 on the lands 22a and 32a of the carrier substrates 24 and 36 in order to mount the carrier substrates 21 and 31 on the carrier substrate 11 has been described. On the other hand, the protruding electrodes 24 and 36 may be formed on the lands 12c of the carrier substrate 11.

Moreover, in the embodiment described above, a method of mounting the semiconductor chip 13 on the carrier substrate 11 by ACF bonding has been described. On the other hand, other adhesive bonding such as NCF (Nonconductive Film) bonding, for example, may be used, and metal bonding such as solder bonding and alloy bonding may be used. Moreover, although a method of using wire bonding when mounting the semiconductor chips 23a-23c, and 33a-33c on the carrier substrate 21 and 31, respectively, has been described, the semiconductor chips 23a-23c, and 33a-33c may be flip-chip mounted on the carrier substrates 21 and 31. Furthermore, although in the embodiment described above, a method of mounting only one semiconductor chip 13 on the carrier substrate 11, as an example, has been described, a plurality of semiconductor chips may be mounted on the carrier substrate 11.

Moreover, the gap between semiconductor packages PK11, PK12 and PK13 may be filled with resin. Accordingly, because the impact resistance of the semiconductor packages PK11, PK12, and PK13 can be improved, cracks can be prevented from being induced in the protruding electrodes 26 and 36 even when residual stress concentrates on the root of the protruding electrodes 26 and 36, thereby the reliability of the semiconductor packages PK11, PK12, and PK13 can be improved.

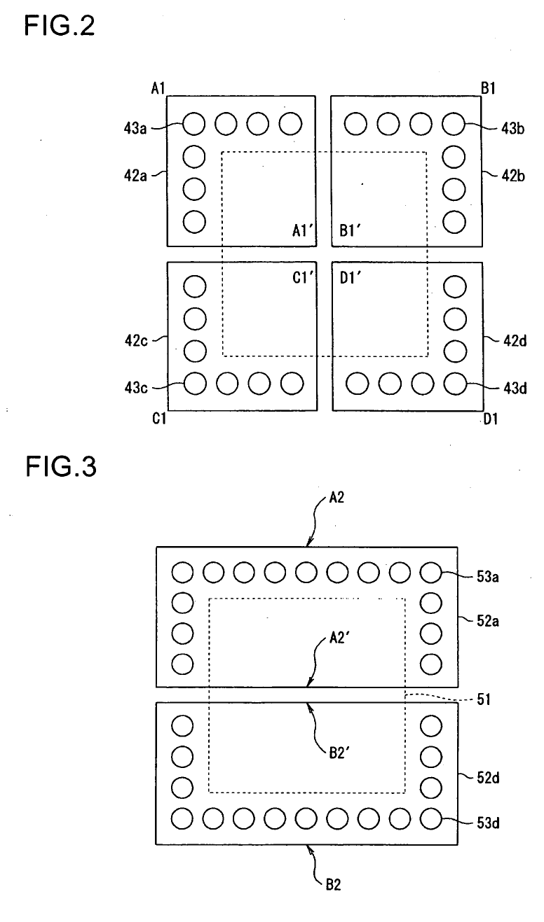

FIG. 2 is a plan view showing a method of arranging protruding electrodes according to a second embodiment of the present invention. In the second embodiment, carrier substrates 42a-42d are arranged in a four-divided manner above a semiconductor chip 41.

In FIG. 2, on the carrier substrates 42a-42d, protruding electrodes 43a-43d are arranged in an L-shape along two sides which intersect at vertexes A1-D1 of each of the carrier substrates 42a-42d, respectively. Then, along two sides which intersect at vertexes A1″-D1′ which are opposite each of the vertexes A1-D1 of the carrier substrates 42a-42d, regions where the protruding electrodes 43a-43d are not arranged are provided, respectively.

Then, with the vertexes A1′-D1′ of the carrier substrates 42a-42d being arranged above the semiconductor chip 41, respectively, the protruding electrodes 43a-43d, which are formed on the carrier substrates 42a-42d, are bonded to a lower layer substrate where the semiconductor chip 41 is mounted. Accordingly, the plurality of carrier substrates 42a-42d can be arranged above the same semiconductor chip 41 by adjusting the position for arranging the protruding electrodes 43a-43d, thereby the effectiveness in saving space can be improved, while preventing the complication of the manufacturing process.

FIG. 3 is a plan view showing a method of arranging protruding electrodes according to a third embodiment of the present invention. In the third embodiment, carrier substrates 52a and 52b are arranged in a two-divided manner above a semiconductor chip 51.

In FIG. 3, on the carrier substrates 52a and 52b, protruding electrodes 53a and 53b are arranged in a U-shape, respectively, along sides A2 and B2 of each of the carrier substrates 52a and 52b, and along the sides which intersect the sides A2 and B2 respectively. Then, along sides A2′ and B2′ opposite the sides A2 and B2 of the carrier substrates 52a and 52b, regions where the protruding electrodes 53a and 53b are not arranged are provided, respectively.

Then, with the sides A2′ and B2′ of the carrier substrates 52a and 52b being arranged above the semiconductor chip 51, respectively, the protruding electrodes 53a and 53b, which are formed on the carrier substrates 52a and 52b, are bonded to a lower layer substrate where the semiconductor chip 51 is mounted. Accordingly, the plurality of carrier substrates 52a and 52b can be arranged above the same semiconductor chip 51 by adjusting the position for arranging the protruding electrodes 53a and 53b, thereby the effectiveness in saving space can be improved, while preventing the complication of the manufacturing process.

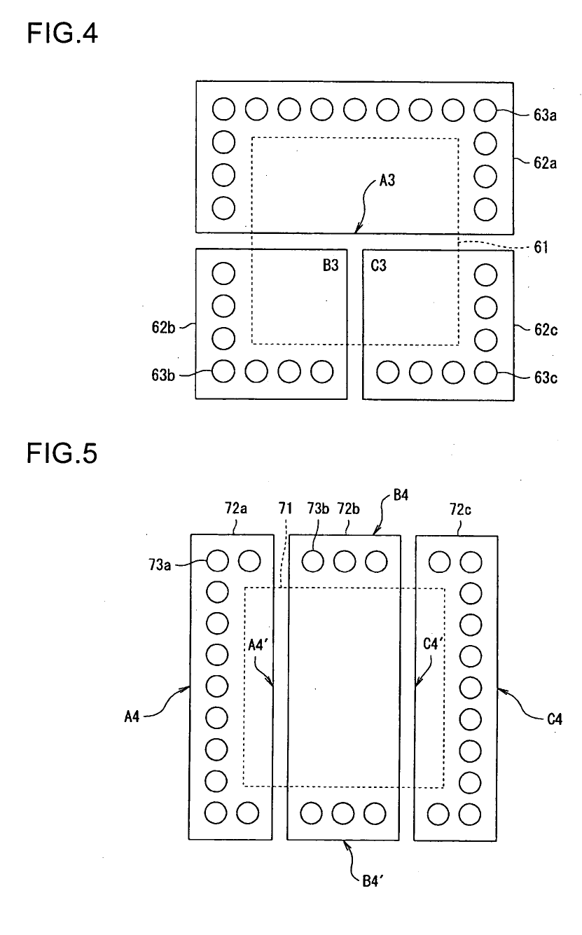

FIG. 4 is a plan view showing a method of arranging protruding electrodes according to a fourth embodiment of the present invention. In the fourth embodiment, carrier substrates 62a-62c are arranged in a three-divided manner above a semiconductor chip 61.

In FIG. 4, in the periphery of the carrier substrate 62a, protruding electrodes 63a are arranged, while avoiding the periphery of a side A3 of the carrier substrate 62a. Moreover, in the peripheries of the carrier substrates 62b and 63c, protruding electrodes 63b and 63c are arranged, while avoiding the peripheries of vertexes B3 and C3 of each of the carrier substrates 62b and 63c, respectively.

Then, with the side A3 of the carrier substrates 62a being arranged above the semiconductor chip 61, the protruding electrodes 63a, which are formed on the carrier substrate 62a, are bonded to a lower layer substrate where the semiconductor chip 61 is mounted. Moreover, with the vertexes B3 and C3 of the carrier substrates 62b and 62c being arranged above the semiconductor chip 61, the protruding electrodes 63b and 63c, which are formed on the carrier substrates 62b and 63c, are bonded to the lower layer substrate where the semiconductor chip 61 is mounted.

Accordingly, the plurality of carrier substrates 62a-62c with different sizes or types can be arranged above the same semiconductor chip 61 by adjusting the position for arranging the protruding electrodes 63a-63c, thereby the effectiveness in saving space can be improved, while preventing the complication of the manufacturing process.

FIG. 5 is a plan view showing a method of protruding electrodes according to a fifth embodiment of the present invention. In the fifth embodiment, carrier substrates 72a-72c are arranged in a three-divided manner above a semiconductor chip 71 so that a carrier substrate 72b may straddle the semiconductor chip 71.

In FIG. 5, on the carrier substrates 72a and 72c, protruding electrodes 73a and 73c are arranged in a U-shaped, respectively, along sides A4 and C4 of each of the carrier substrates 72a and 72c, and along sides which intersect the sides A4 and C4, respectively. Then, along sides A4′ and C4′ opposite the sides A4 and C4 of the carrier substrates 72a and 72c, regions where the protruding electrodes 73a and 73c are not arranged are provided, respectively. On the other hand, on the carrier substrate 72b, protruding electrodes 73b are arranged along sides B4 and B4′ opposite to each other, and regions where the protruding electrodes 73b are not arranged are provided between the sides B4 and B4′.

Then, the protruding electrodes 73a and 73c, which are formed on the carrier substrates 72a and 72c, are bonded to a lower layer substrate where the semiconductor chip 71 is mounted so that the sides A4′ and C4′ of the carrier substrates 72a and 72c are arranged above the semiconductor chip 71. Moreover, the protruding electrodes 73b, which are formed on the carrier substrate 72b, are bonded to the lower layer substrate where the semiconductor chip 71 is mounted so that the carrier substrate 72b straddles the semiconductor chip 71.

Accordingly, even when the carrier substrates 72a-72c are arranged in a three-divided manner above the semiconductor chip 71, the plurality of carrier substrates 72a-72c can be arranged above the same semiconductor chip 71, while supporting the four corners of each of the carrier substrates 72a-72c, respectively, thereby the effectiveness in saving space can be improved, while preventing the complication of the manufacturing process.

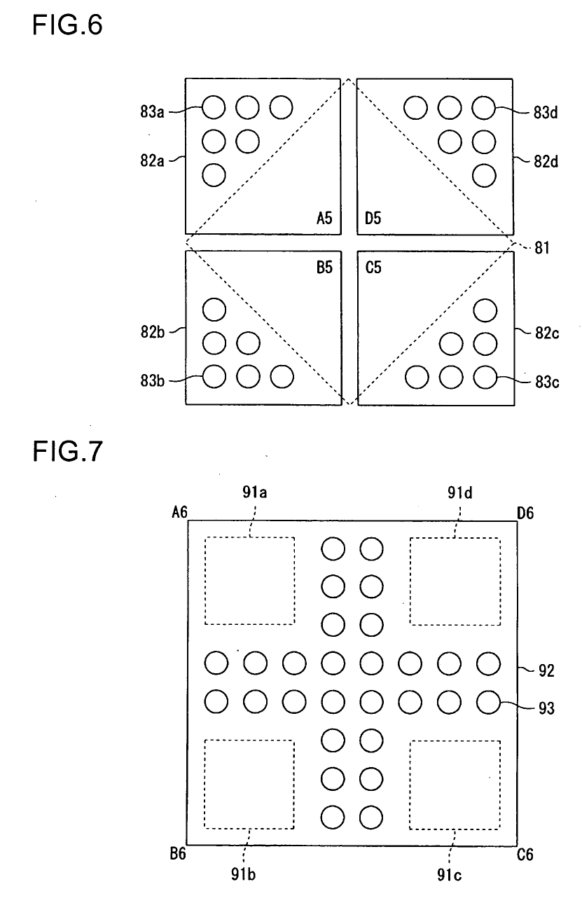

FIG. 6 is a plan view showing a method of arranging protruding electrodes according to a sixth embodiment of the present invention. In the sixth embodiment, carrier substrates 82a-82d are arranged in a four-divided manner above a semiconductor chip 81 so that the orientation of the carrier substrates 82a-82d are different from that of the semiconductor chip 81.

In FIG. 6, protruding electrodes 83a-83d are arranged on the carrier substrates 82a-82d, respectively, while avoiding the peripheries of vertexes A5-D5 of each of the carrier substrate 82a-82d. Then, for example, in a condition where the,semiconductor chip 81 is at an angle of 45 degrees with respect to the carrier substrates 82a-82d, the protruding electrodes 83a-83d are bonded to a lower layer substrate where the semiconductor chip 81 is mounted so that the vertexes A5-D5 of the carrier substrates 82a-82d are arranged above the semiconductor chip 81. Accordingly, by adjusting the position for arranging the protruding electrodes 83a-83d, the plurality of carrier substrates 82a-82d can be arranged above the same semiconductor chip 81 with different orientation. Thereby the effectiveness in saving space can be improved, while preventing the complication of the manufacturing process.

FIG. 7 is a plan view showing a method of arranging protruding electrodes according to a seventh embodiment of the present invention. In the seventh embodiment, semiconductor chips 91a-91d are arranged in a four-divided manner under a carrier substrate 92.

In FIG. 7, protruding electrodes 93 are arranged on the carrier substrate 92, while avoiding the peripheries of vertexes A6-D6 of the carrier substrate 92. Then, the protruding electrodes 93 are bonded to a lower layer substrate where the semiconductor chips 91a-91d are mounted so that the carrier substrate 92 is arranged above the semiconductor chips 91a-91d. Accordingly, the same carrier, substrate 92 can be arranged above the plurality of semiconductor chips 91a-91d by adjusting the position for arranging the protruding electrode 93, thereby the effectiveness in saving space can be improved, while preventing the complication of the manufacturing process.

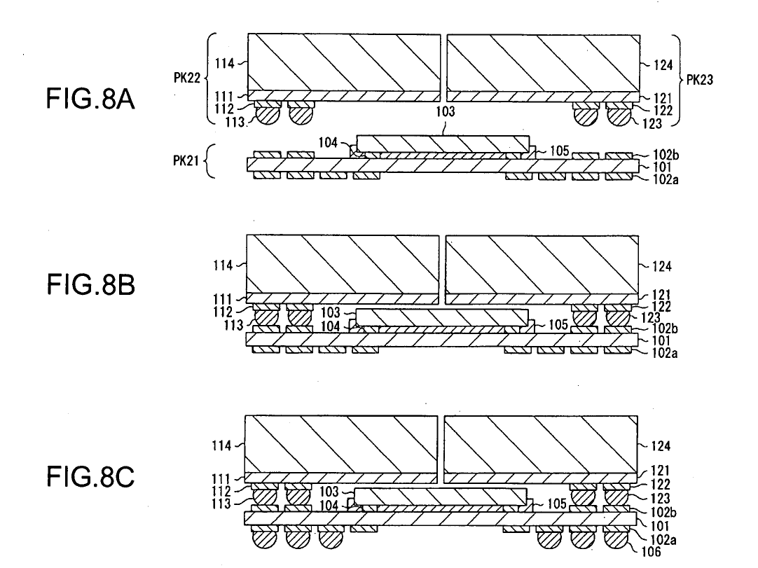

FIG. 8 is sectional views showing a method of manufacturing a semiconductor device according to an eighth embodiment of the present invention. In the eighth embodiment, semiconductor packages PK22 and PK23 are mounted on a semiconductor package PK21 so that the ends of the semiconductor packages PK22 and PK23 overlap a semiconductor chip 103.

In FIG. 8(a), the semiconductor package PK21 has a carrier substrate 101 provided therein, and lands 102a and 102b are formed on both sides of the carrier substrate 101, respectively. Then, on the carrier substrate 101, the semiconductor chip 103 is flip-chip mounted, and protruding electrodes 104 for flip-chip mounting are formed on the semiconductor chip 103. Then, the protruding electrodes 104, which are formed on the semiconductor chip 103, are bonded by ACF bonding to the lands 102b through an anisotropic conductive sheet 105.

On the other hand, the semiconductor packages PK22 and PK23 have carrier substrates 111 and 121 provided therein, respectively, and lands 112 and 122 are formed on the back surfaces of the carrier substrates 111 and 121, respectively, and protruding electrodes 113 and 123 such as solder balls, are formed on the lands 112 and 122, respectively. Moreover, on the carrier substrates 111 and 121, semiconductor chips are mounted, and the whole surfaces of the carrier substrates 111 and 121, where the semiconductor chips are mounted, are sealed by sealing resin 114 and 124, respectively. In addition, on the carrier substrates 111 and 121, the semiconductor chips which are wire bonded may be mounted, or the semiconductor chips may be flip-chip mounted, or a stacked structure of the semiconductor chips may be mounted.

Then, when stacking the semiconductor packages PK22 and PK23 on the semiconductor package PK21, a flux or a soldering paste is applied to the lands 102b of the carrier substrate 101.

Next, as shown in FIG. 8 (b), by mounting the semiconductor packages PK22 and PK23 separated from each other on the semiconductor package PK21, and executing a reflow processing, the protruding electrodes 113 and 123 are bonded to the lands 102b.

Accordingly, the plurality of semiconductor packages PK22 and PK23 can be arranged above the same semiconductor chip 103 by adjusting the position for arranging the protruding electrodes 113 and 123, which are arranged on the carrier substrates 111 and 121. Thus the mounting area can be reduced, while preventing the complication of the manufacturing process. Moreover, by stacking the semiconductor packages PK22 and PK23 on the semiconductor package PK21, only inspected good semiconductor packages PK21, PK22, and PK23 are selected to be mounted, thereby the manufacturing yield can be increased.

Next, as shown in FIG. 8 (c), protruding electrodes 106 for mounting the carrier substrate 101 on a motherboard is formed on the lands 102a, which are formed on the back surface of the carrier substrate 101.

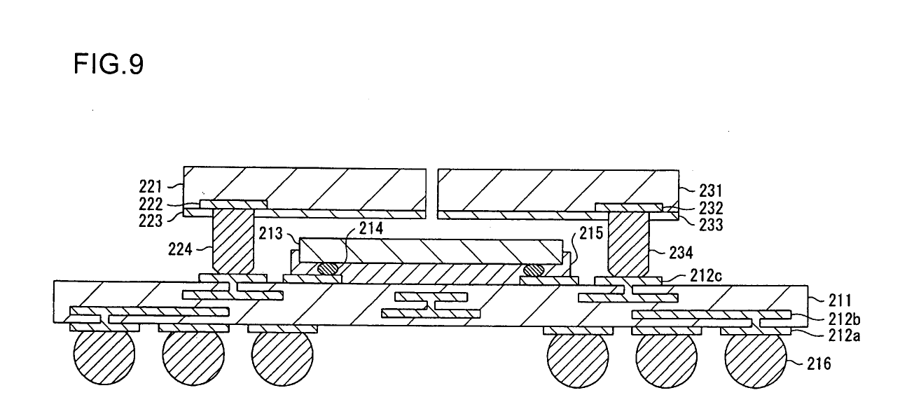

FIG. 9 is a sectional view showing a structure of a semiconductor device according to a ninth embodiment of the present invention. In the ninth embodiment, semiconductor chips 213, 221, and 231 are flip-chip mounted on a carrier substrate 211 so that the ends of the semiconductor chips 221 and 231 are arranged above the semiconductor chip 213.

In FIG. 9, while lands 212a and 212c are formed on both sides of the carrier substrate 211, respectively, internal wirings 212b are formed inside the carrier substrate 211. Then, on the carrier substrate 211, the semiconductor chip 213 is flip-chip mounted, and protruding electrodes 214 for flip-chip mounting are formed on the semiconductor chip 213. Then, the protruding electrodes 214, which are formed on the semiconductor chip 213, are bonded by ACF bonding to the lands 212c through an anisotropic conductive sheet 215. In addition, when mounting the semiconductor chip 213 on the carrier substrate 211, besides a method of using ACF bonding, other adhesive bonding such as NCF bonding may be used, or metal bonding such as solder bonding and alloy bonding may be used. Moreover, on the lands 212a formed on the back surface of the carrier substrate 211, protruding electrodes 216 for mounting the carrier substrate 211 on a motherboard is formed.

On the other hand, on the semiconductor chips 221 and 231, while electrode pads 222 and 232 are formed respectively, insulating layers 223 and 233 are formed so that the electrode pads 222 and 232 are exposed, respectively. Then, on the electrode pads 222 and 233, protruding electrodes 224 and 234 for flip-chip mounting the semiconductor chips 221 and 231 are formed, respectively, so that the ends of the semiconductor chips 221 and 231 are held above the semiconductor chip 213.

Here, the protruding electrodes 224 and 234 can be arranged, while avoiding the mounting region of the semiconductor chip 213, and for example, the protruding electrodes 224 and 234 can be arranged in a U-shape, in an L-shape, or in a G-shape. Then, the semiconductor chips 221 and 231 are flip-chip mounted on the carrier substrate 211 so that the protruding electrodes 224 and 234 are bonded to the lands 212c formed on the carrier substrate 211, and the ends of the semiconductor chips 221 and 231 are arranged above the semiconductor chip 213.

Accordingly, even when the types or sizes of the semiconductor chips 213, 221, and 231 are different, the semiconductor chips 221 and 231 can be flip-chip mounted above the semiconductor chip 213, without interposing carrier substrates between the semiconductor chips 213, 221 and 231. For this reason, the mounting area can be reduced, while suppressing an increase in height when stacking the semiconductor chips 213 and 221 and 231, thereby the effectiveness in saving space can be improved.

In addition, when mounting the semiconductor chips 221 and 231 on the carrier substrate 211, the semiconductor chips 221 and 231 may closely contact the semiconductor chip 213, or the carrier substrates 221 and 231 may be spaced apart from the semiconductor chip 213. Moreover, when mounting the semiconductor chips 221 and 231 on the carrier substrate 211, adhesive bonding such as ACF bonding and NCF bonding may be used, or metal bonding such as solder bonding and alloy bonding may be used. Moreover, as for the protruding electrodes 212, 214, 224 and 234, for example, an Au bump, Cu bump or Ni bump covered with a solder material and the like, a solder ball, or the like may be used. Moreover, the gap between the semiconductor chips 221, 231 and the carrier substrate 211 may be filled with sealing resin.

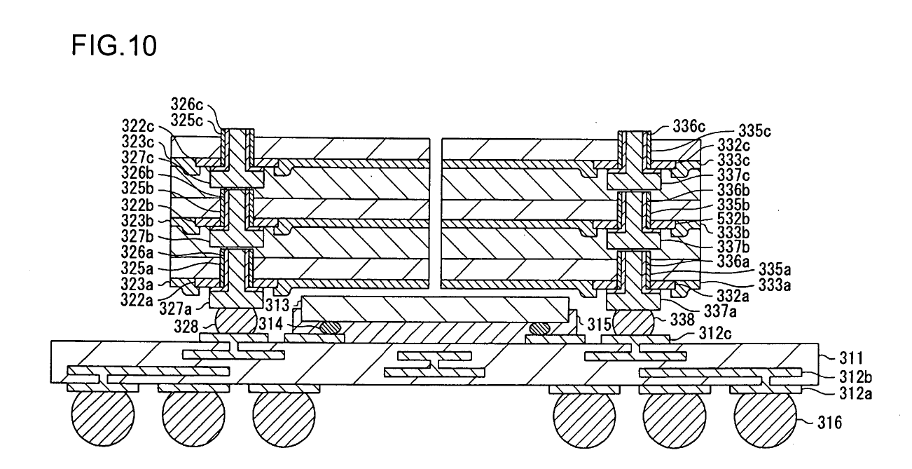

FIG. 10 is a sectional view showing a structure of a semiconductor device according to a tenth embodiment of the present invention. In addition, in the tenth embodiment, semiconductor chips 321a-321c and 331a-331c of a stacked structure are flip-chip mounted on a carrier substrate 311 so that the ends of the semiconductor chips 321a-321c and 331a-331c of a stacked structure are arranged above a semiconductor chip 313.

In FIG. 10, while lands 312a and 312c are formed on both sides of the carrier substrate 311 internal wirings 312b are formed inside the carrier substrate 311. Then, on the carrier substrate 311, the semiconductor chip 313 is flip-chip mounted, and protruding electrodes 314 for flip-chip mounting are formed on the semiconductor chip 313. Then, the protruding electrodes 314, which are formed on the semiconductor chip 313, are bonded to the lands 312c by ACF bonding through an anisotropic conductive sheet 315. In addition, when mounting the semiconductor chip 313 on the carrier substrate 311, besides a method of using ACF bonding, other adhesive bonding such as, for example, NCF bonding may be used, or metal bonding such as solder bonding and alloy bonding may be used. Moreover, on the lands 312a formed on the back surface of the carrier substrate 311, protruding electrodes 316 for mounting the carrier substrate 311 on a motherboard are formed.

On the other hand, on the semiconductor chips 321a-321c and 331a-331c, while electrode pads. 322a-322c and 332a-332c are formed, respectively, insulating layers 323a-323c and 333a-333c are formed so that the electrode pads 322a-322c and 332a-332c are exposed, respectively. Then, in the semiconductor chips 321a-321c and 331a-331c, for example, through-holes 324a-324c and 334a-334c are formed corresponding to the positions of the electrode pads 322a-322c and 332a-332c, respectively. While inside each of the through-holes 324a-324c and 334a-334c, through-hole electrodes 327a-327c and 337a-337c are formed through insulating layers 325a-325c and 335a-335c and through conductive films 326a-326c and 336a-336c, respectively. Then, the semiconductor chips 321a-321c and 331a-331c, where the through-hole electrodes 327a-327c and 337a-337c are formed, respectively, are stacked through the through-hole electrodes 327a-327c and 337a-337c, respectively. Furthermore, resin 328a, 328b, 338a, and 338b is injected into the gaps between the semiconductor chips 321a-321c and 331a-331c, respectively.

Then, on each of the through-hole electrodes 327a and 337a, which are formed in the semiconductor chips 321a and 331a, respectively, protruding electrodes 329 and 339 for flip-chip mounting the stacked structures of the semiconductor chips 321a-321c and 331a-331c are formed so that the ends of the stacked structures of the semiconductor chips 321a-321c and 331a-331c are held above the semiconductor chip 313.

Here, the protruding electrodes 329 and 339 can be arranged, while avoiding the mounting region of the semiconductor chip 313, and for example, the protruding electrodes 329 and 339 can be arranged in a U-shape, in an L-shape, or in a G-shape. Then, the semiconductor chips 321a-321c and 331a-331c of a stacked structure are flip-chip mounted on the carrier substrate 311 so that the protruding electrodes 329 and 339 are bonded to the lands 312c, which are formed on the carrier substrate 311, and the ends of the semiconductor chips 321a-321c and 331a-331c of a stacked structure are arranged above the semiconductor chip 313.

Accordingly, the stacked structures of the semiconductor chips 321a-321c and 331a-331c can be flip-chip mounted on the semiconductor chip 313, without interposing carrier substrates between the stacked structures of the semiconductor chips 321a-321c and 331a-331c, and the semiconductor chip 313. This enables the plurality of semiconductor chips 321a-321c and 331a-331c, which are different types from that of the semiconductor chip 313, can be stacked while suppressing an increase in height when stacking.

Moreover, when mounting the stacked structures of the semiconductor chips 321a-321c and 331a-331c on the carrier substrate 311, for example, adhesive bonding such as ACF bonding and NCF bonding may be used, or metal bonding such as solder bonding and alloy bonding may be used. Moreover, as for the protruding electrodes 314, 314, 329, and 329, for example, an Au bump, Cu bump or Ni bump covered with a solder material and the like, a solder ball, or the like may be used. Moreover, although in the embodiment described above, a method of mounting a three-layer structure of the semiconductor chips 321a-321c and 331a-331c on the carrier substrate 311 has been described, a stacked structure of semiconductor chips which are mounted on the carrier substrate 311 may be of two layers or four layers or more. Moreover, the gaps between the semiconductor chips 321a, 331a and the carrier substrate 311 may be filled with sealing resin.

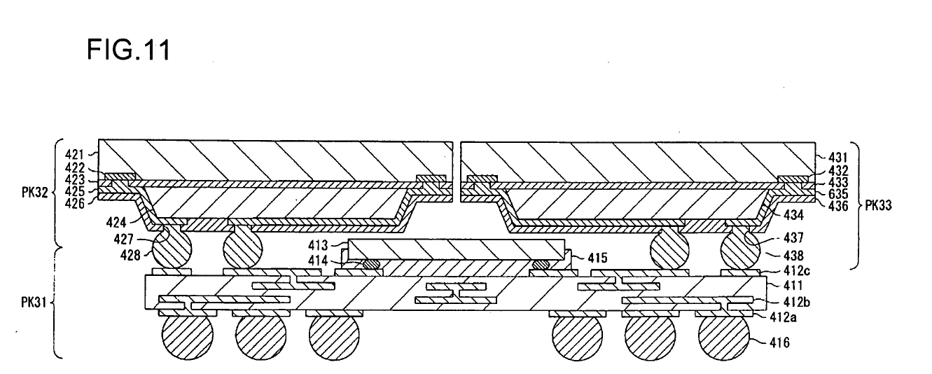

FIG. 11 is a sectional view showing a structure of a semiconductor device according to an eleventh embodiment of the present invention. In the eleventh embodiment, a plurality of W-CSPs (wafer level-chip-size packages) are mounted on a carrier substrate 411 so that the ends of the W-CSPs are arranged above a semiconductor chip 413.

In FIG. 11, while a semiconductor package PK31 has the carrier substrate 411 provided therein, and lands 412a and 412c are formed on both sides of the carrier substrate 411, respectively, and internal wirings 412b are formed inside the carrier substrate 411. Then, on the carrier substrate 411, the semiconductor chip 413 is flip-chip mounted, and protruding electrodes 414 for flip-chip mounting are formed on the semiconductor chip 413. Then, the protruding electrodes 414, which are formed on the semiconductor chip 413, are bonded by ACF bonding to the lands 412c through an anisotropic conductive sheet 415. Moreover, on the lands 412a formed on the back surface of the carrier substrate 411, protruding electrodes 416 for mounting the carrier substrate 411 on a motherboard are formed.

On the other hand, semiconductor packages PK32 and PK33 have semiconductor chips 421 and 431 provided therein, respectively, and on each of the semiconductor chips 421 and 431, while electrode pads 422 and 432 are formed, respectively, insulating layers 423 and 433 are formed, respectively, so that each of the electrode pads 422 and 432 is exposed. Then, on each of the semiconductor chips 421 and 431, stress relieving layers 424 and 435 are formed so that each of the electrode pads 422 and 432 is exposed, respectively. Furthermore, on each of the electrode pads 422 and 432, re-routing wirings 425 and 435 which are extended on the stress relieving layers 424 and 435 are formed, respectively. Then, on each of the re-routing wirings 425 and 435, solder-resist films 426 and 436 are formed, respectively, and on each of the solder-resist films 426 and 436, openings 427 and 437 which expose the re-routing wirings 425 and 435 on each of the stress relieving layers 424 and 435, respectively, are formed. Then, on the re-routing wirings 425 and 435, which are exposed through each of the openings 427 and 437, respectively, protruding electrodes 428 and 438 for face-down mounting the semiconductor chips 421 and 431 on the carrier substrate 411, respectively, are formed so that the ends of the semiconductor chips 421 and 431 are held above the semiconductor chip 413.

Here, the protruding electrodes 428 and 438 can be arranged, while avoiding the mounting region of the semiconductor chip 413, and for example, the protruding electrodes 428 and 438 can be arranged in a U-shape, in an L-shape, or in a G-shape. Then, the semiconductor packages PK32 and PK33 are mounted on the carrier substrate 411 so that the protruding electrodes 428 and 438 are bonded to the lands 412c, which are formed on the carrier substrate 411, and the ends of the semiconductor chips 421 and 431 are arranged above the semiconductor chip 413.

Accordingly, the W-CSPs can be stacked on the carrier substrate 411 where the semiconductor chip 413 is flip-chip mounted, and thus even when the types or sizes of the semiconductor chips 413, 421 and 431 are different, the semiconductor chips 421 and 431 can be three-dimensionally mounted on the semiconductor chip 413 without interposing carrier substrates between the semiconductor chips 413, 421 and 431. For this reason, the mounting area can be reduced, while suppressing an increase in height when stacking the semiconductor chips 413, 421 and 431, thereby enabling the effectiveness in saving space to be improved.

In addition, when mounting the semiconductor packages PK32 and PK33 on the carrier substrate 411, the semiconductor packages PK32 and PK33 may closely contact the semiconductor chip 413, or the semiconductor packages PK32 and PK33 may be spaced apart from the semiconductor chip 413. Moreover, when mounting the semiconductor packages PK32 and PK33 on the carrier substrate 411, adhesive bonding such as ACF bonding and NCF bonding may be used, or metal bonding such as solder bonding and alloy bonding may be used. Moreover, as for the protruding electrodes 414, 416, 428, and 438, for example, an Au bump, Cu bump or Ni bump covered with a solder material and the like, a solder ball, or the like may be used.

In addition, the semiconductor devices and the electronic devices described above are applicable to electronic equipment such as a liquid crystal display device, a cellular phone, Personal Digital Assistant, a video camera, a digital camera, and an MD (Mini Disc) player, and thus enable weight savings and miniaturization of electronic equipment to be attained, while enabling the functional performance of the electronic equipment to be improved.

Moreover, although in the embodiments described above, methods of mounting semiconductor chips or semiconductor packages, as examples, have been described, the present invention is not necessarily limited to the methods of mounting semiconductor chips or semiconductor packages, and, for example, a ceramic element such as a surface acoustic wave (SAW) element, optical elements such as a light modulator and an optical switch, and various sensors such as a magnetic sensor and a bio-sensor may be mounted.

What is claimed is:

1. A semiconductor device, comprising:
a rectangle-shaped carrier substrate which has a first region including two sides adjacent to each other, and a second region which adjoins the first region with one diagonal line as a border and whose shape is symmetrical with respect to the first region;
a semiconductor chip mounted on the carrier substrate;
a first protruding electrode group arranged in an L-shape along the two sides of the first region; and
a second protruding electrode group arranged on the second region so as to be asymmetrical with the arrangement of the first protruding electrode group.

2. A semiconductor device, comprising:
a rectangle-shaped carrier substrate;
a semiconductor chip mounted on the carrier substrate;
a region without a protruding electrode that is provided along at least two sides which intersect at a first vertex of the carrier substrate; and
a protruding electrode group which is provided along at least two sides which intersect at a second vertex of the carrier substrate opposite the first vertex.

3. A semiconductor device, comprising:
a rectangle-shaped carrier substrate;
a semiconductor chip mounted on the carrier substrate;
a region without a protruding electrode which is provided along at least a first side of the carrier substrate; and
a protruding electrode group which is provided along a second side of the carrier substrate opposite the first side, and along at least a third side which intersects the second side.

4. The semiconductor device according to claim 3, wherein the protruding electrode group is arranged in a U-shape.

5. A semiconductor device, comprising:
a carrier substrate; and
a protruding electrode arranged on the carrier substrate, excluded from a region where a semiconductor chip is mounted so as to be arranged to be overlapped by an end of the carrier substrate.

6. A semiconductor device, comprising:
a carrier substrate;
a semiconductor chip mounted on the carrier substrate;
a plurality of land electrodes formed on the carrier substrate; and
a protruding electrode arranged on a part of the plurality of land electrodes.

7. A semiconductor device, comprising:
a first carrier substrate;
a first semiconductor chip mounted on the first carrier substrate;
a rectangle-shaped second carrier substrate;
a second semiconductor chip mounted on the second carrier substrate;
a region without a protruding electrode that is provided along at least two sides which intersect at a first vertex of the second carrier substrate; and
a protruding electrode group which is provided along at least two sides which intersect at a second vertex of the second carrier substrate opposite the first vertex, and which is bonded to the first carrier substrate so as to arrange the first semiconductor chip under the region without a protruding electrode.

8. A semiconductor device, comprising:
a first carrier substrate;
a first semiconductor chip mounted on the first carrier substrate;
a rectangle-shaped second carrier substrate;
a second semiconductor chip mounted on the second carrier substrate;
a region without a protruding electrode which is provided along at least a first side of the second carrier substrate; and
a protruding electrode group which is provided along a second side of the second carrier substrate opposite the first side, and along at least a third side which intersects the second side, and which is bonded to the first carrier substrate so as to arrange the first semiconductor chip under the region without a protruding electrode.

9. A semiconductor device, comprising:
a first carrier substrate;
a first semiconductor chip mounted on the first carrier substrate, a rectangle-shaped second semiconductor chip;
a region without a protruding electrode that is provided along at least two sides which intersect at a first vertex of the second semiconductor chip; and
a protruding electrode group which is provided along at least two sides which intersect at a second vertex of the second semiconductor chip opposite the first vertex, and which is bonded to the first carrier substrate so as to arrange the first semiconductor chip under the region without a protruding electrode.

10. A semiconductor device, comprising:
a first carrier substrate;
a first semiconductor chip mounted on the first carrier substrate, a rectangle-shaped second semiconductor chip;
a region without a protruding electrode which is provided along at least a first side of the second semiconductor chip; and
a protruding electrode group which is provided along a second side of the second semiconductor chip opposite the first side, and along at least a third side which intersects the second side, and which is bonded to the first carrier substrate so as to arrange the first semiconductor chip under the region without a protruding electrode.

11. An electronic device, comprising:
a first carrier substrate;
a first electronic component mounted on the first carrier substrate;
a rectangle-shaped second carrier substrate;
a second electronic component mounted on the second carrier substrate;
a region without a protruding electrode that is provided along at least two sides which intersect at a first vertex of the second carrier substrate; and
a protruding electrode group which is provided along at least two sides which intersect at a second vertex of the second carrier substrate opposite the first vertex, and which is bonded to the first carrier substrate so as to arrange the first electronic component under the region without a protruding electrode.

12. An electronic device, comprising:
a first carrier substrate;
a first electronic component mounted on the first carrier substrate;
a rectangle-shaped second carrier substrate;
a second electronic component mounted on the second carrier substrate;
a region without a protruding electrode which is provided along at least a first side of the second carrier substrate; and
a protruding electrode group which is provided along a second side of the second carrier substrate opposite the first side, and along at least a third side which intersects the second side, and which is bonded to the first carrier substrate so as to arrange the first electronic component under the region without a protruding electrode.

13. Electronic equipment, comprising:
a first carrier substrate;
a first semiconductor chip mounted on the first carrier substrate;
a rectangle-shaped second carrier substrate;
a second semiconductor chip mounted on the second carrier substrate;
a region without a protruding electrode that is provided along at least two sides which intersect at a first vertex of the second carrier substrate;
a protruding electrode group which is provided along at least two sides which intersect at a second vertex of the second carrier substrate opposite the first vertex, and which is bonded to the first carrier substrate so as to arrange the first semiconductor chip under the region without a protruding electrode; and
a motherboard where the first carrier substrate is mounted.

14. Electronic equipment, comprising:
a first carrier substrate;
a first semiconductor chip mounted on the first carrier substrate;
a rectangle-shaped second carrier substrate;
a second semiconductor chip mounted on the second carrier substrate;
a region without a protruding electrode which is provided along at least a first side of the second carrier substrate;
a protruding electrode group which is provided along a second side of the second carrier substrate opposite the first side, and along at least a third side which intersects the second side, and which is bonded to the first carrier substrate so as to arrange the first semiconductor chip under the region without a protruding electrode; and
a motherboard where the first carrier substrate is mounted.

15. A method of manufacturing a semiconductor device, comprising:
mounting a first semiconductor chip on a first carrier substrate;
mounting a second semiconductor chip on a second carrier substrate;
forming a protruding electrode group on the second carrier substrate while avoiding the periphery of at least one side of the second carrier substrate; and
bonding the protruding electrode group to the first carrier substrate so as to arrange the at least one side of the second carrier substrate on or above the first semiconductor chip.

16. A method of manufacturing a semiconductor device, comprising:
mounting a first semiconductor chip on a first carrier substrate;
mounting a second semiconductor chip on a second carrier substrate;
forming a protruding electrode group on the second carrier substrate while avoiding the periphery of at least one vertex of the second carrier substrate; and
bonding the protruding electrode group to the first carrier substrate so as to arrange the at least one vertex of the second carrier substrate on or above the first semiconductor chip.
